(19) United States
(12) Patent Application Publication
(10) Pub. No.: US 2010/0261121 A1
(43) Pub. Date: Oct. 14, 2010

(54) PATTERN FORMING METHOD

(76) Inventors: Masanori TAKAHASHI, Kanagawa (JP); Satoshi Tanaka, Kanagawa (JP); Soichi Inoue, Kanagawa (JP); Akiko Mimotogi, Kanagawa (JP); Katsuyoshi Kodera, Kanagawa (JP); Takamasa Takaki, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/717,423

(22) Filed: Mar. 4, 2010

(30) Foreign Application Priority Data
Apr. 10, 2009 (JP) 2009-096488

(51) Int. Cl. G03F 7/20

(52) U.S. Cl. 430/325

(57) ABSTRACT

To provide a pattern forming method comprising: laminating a resist layer on a substrate; forming a diffraction pattern having an opening opened at a predetermined pitch p for diffracting exposure light on an upper layer side of the resist layer; performing whole image exposure with respect to the diffraction pattern in which a refractive index with respect to the exposure light is n, with diffracted light acquired by irradiation of exposure light having a wavelength λ from above the diffraction pattern, which is then diffracted by the diffraction pattern; and forming a desired pattern on a lower layer side of the resist pattern by using a resist pattern formed by developing the resist layer, wherein the predetermined pitch p, the wavelength λ, and the refractive index n satisfy a condition of p>λ/n.

### CROSS-REFERENCE TO RELATED APPLICATIONS

This application is based upon and claims the benefit of priority from the prior Japanese Patent Application No. 2009-096488, filed on Apr. 10, 2009; the entire contents of which are incorporated herein by reference.

### BACKGROUND OF THE INVENTION

1. Field of the Invention

The present invention relates to a pattern forming method.

2. Description of the Related Art

In a lithographic process at the time of manufacturing a semiconductor device, to form a fine pattern, an exposure apparatus including a mask (reticle) fourfold the size of a pattern actually formed and a reduction projection optical system is used.

Recently, however, formation of a mask pattern has become difficult even by using the fourfold mask, as the pattern becomes much finer. Furthermore, due to design limitation of an optical system and physical limitation of members, the size of the pattern that can be formed on a wafer approaches its limit. As resolution enhancement techniques (RET) with respect to these problems, a new exposure technique such as double patterning has been proposed. However, double patterning has various problems to be solved, such as misalignment caused at the time of superposition of first exposure and second exposure, and thus it is not an easy technique to use.

As a method for solving such problems, a technique for forming a fine pattern by using whole image exposure such that a pattern on a wafer formed by an existing exposure technique is operated as a shifter has been proposed (see Japanese Patent Application Laid-Open No. H5-47623).

However, with the technique proposed in Japanese Patent Application Laid-Open No. H5-47623, although reduction of the pattern size is possible, because a fine pattern is formed by shifting a phase of light transmitting through depressions and projections of a resist, respectively, to negate both lights, a pattern can be formed only below edges of the depressions and projections of the resist. Further, the pattern formed below the edges is limited to a fine pattern, thereby only achieving low flexibility in pattern designing.

### BRIEF SUMMARY OF THE INVENTION

A pattern forming method according to an embodiment of the present invention comprises: laminating a first resist layer on an upper layer side of a pattern forming layer used for forming a desired pattern on a substrate; forming a diffraction pattern having an opening opened at a predetermined pitch p for diffracting exposure light on an upper layer side than the first resist layer; performing whole image exposure with respect to the diffraction pattern in which a refractive index with respect to the exposure light is n, with diffracted light acquired by irradiation of exposure light having a wavelength λ from above the diffraction pattern, which is then diffracted by the diffraction pattern; and forming a desired pattern on the pattern forming layer by using a resist pattern formed by developing the first resist layer, wherein the predetermined pitch p of the diffraction pattern, the wavelength λ of the exposure light, and the refractive index n satisfy a condition of p>λ/n.

A pattern forming method according to an embodiment of the present invention comprises: laminating a first resist layer on an upper layer side of a pattern forming layer used for forming a desired pattern on a substrate; forming a second resist layer on an upper layer side than the first resist layer, and forming a diffraction pattern having a predetermined opening for diffracting exposure light by applying a lithography process using exposure light of a first wavelength to the second resist layer; performing exposure with respect to the first resist layer with diffracted light acquired by irradiation of exposure light having a second wavelength smaller than the first wavelength by whole image exposure from above the diffraction pattern, which is then diffracted by the diffraction pattern; and forming a desired pattern on the pattern forming layer by using the resist layer formed by developing the first resist layer.

A computer program product having a computer readable medium including programmed instructions that can be executed on a computer and are for calculating an optical image to a resist, according to an embodiment of the present invention, wherein the instructions, when executed by the computer, cause the computer to perform: calculating an optical image to a first resist layer when performing whole image exposure with respect to a diffraction pattern in which a refractive index with respect to exposure light is n, with diffracted light acquired by irradiation of the exposure light having a wavelength λ from above the diffraction pattern, which is then diffracted by the diffraction pattern, with respect to a substrate on which the first resist layer is laminated on an upper layer side of a pattern forming layer used for forming a desired pattern and the diffraction pattern having an opening opened at a predetermined pitch p for diffracting the exposure light is formed on an upper layer side of the first resist layer.

### BRIEF DESCRIPTION OF THE DRAWINGS

FIG. 1 is a sectional view of a configuration of a diffraction pattern and a resist layer according to an embodiment of the present invention;

FIGS. 2A to 2J depict a pattern forming process procedure with respect to a pattern forming layer;

FIG. 3 is a schematic diagram for explaining a relation between an arrangement position of a first resist layer and a light intensity distribution;

FIGS. 4A to 4C depict configuration examples of a resist pattern with respect to a diffraction pattern;

FIGS. 5A and 5B are schematic diagram for explaining a relation between a size of a diffraction pattern and a light intensity distribution;

FIG. 6 is a block diagram of a configuration of a mask-pattern correcting device;

FIG. 7 depicts a hardware configuration of the mask-pattern correcting device;

FIG. 8 is a flowchart of a correction process procedure of a mask pattern based on a light intensity distribution;

FIGS. 9A to 9C depict an example of a diffraction pattern and a light intensity distribution as viewed from above;

FIGS. 10A to 10C are schematic diagram for explaining various layers arranged between a diffraction pattern and a resist layer;

FIG. 11 depicts a light intensity distribution when a desired pattern is formed at a position other than a pattern edge of a diffraction pattern; and

FIG. 12 depicts a light intensity distribution when an isolated pattern is used.

### DETAILED DESCRIPTION OF THE INVENTION

Exemplary embodiments of a pattern forming method according to the present invention will be explained below in detail with reference to the accompanying drawings. The present invention is not limited to the following embodiments.

In an embodiment of the present invention, a diffraction pattern for diffracting exposure light is formed on an upper layer than a layer in which a desired pattern formation is performed (a pattern forming layer), to perform whole image exposure from above the diffraction pattern. Accordingly, various patterns of desired sizes finer than the diffraction pattern in the upper layer are formed.

The whole image exposure is an exposure method in which the whole surface of a substrate (not shown) such as a wafer on which the diffraction pattern for diffracting exposure light is formed is irradiated with exposure light without using a mask to expose a resist layer (a resist layer 3X to be described later) formed below the diffraction pattern with diffracted light by the diffraction pattern. The resist layer formed below the diffraction pattern is a layer that functions as a mask when forming a pattern forming layer. The diffraction pattern is a pattern that is formed by using any layer such as a semiconductor, a metal layer, an insulating layer, and a resist layer. An intermediate layer (an intermediate layer 2 to be described later) can be formed between the diffraction pattern and the resist layer 3X.

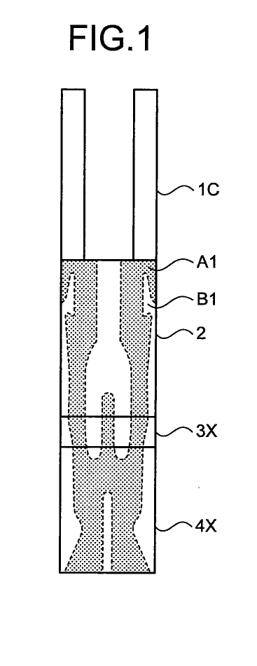

FIG. 1 is a sectional view of a configuration of a diffraction pattern and a resist layer according to the present embodiment. As shown in FIG. 1, in the present embodiment, a pattern forming layer 4X in which pattern formation is performed on a substrate (not shown) such as a wafer is laminated, and the resist layer 3X is laminated above the pattern forming layer 4X. The intermediate layer (an offset layer) 2 is further laminated above the resist layer 3X, and a diffraction pattern (an initial pattern) 1C that functions as a diffraction grating is formed above the intermediate layer 2. The intermediate layer 2 is a film for controlling (adjusting) a distance between the resist layer 3X and the diffraction pattern 1C (an interlayer distance). The diffraction pattern 1C can be a resist pattern after development, or can be a mask material etched by using the resist pattern after development (an after-etching pattern). Further, the diffraction pattern 1C can be a pattern formed by nanoimprint, or a pattern formed by using a sidewall process.

In the present embodiment, at the time of forming a desired pattern on the pattern forming layer 4X, whole image exposure is performed from above the diffraction pattern 1C. At this time, a photomask and a projection optical system are not required because of whole image exposure, and illumination for exposure is irradiated onto the substrate (an upper layer side of the diffraction pattern 1C).

Exposure needs to be performed as whole image exposure under a condition for causing a diffraction phenomenon. The condition for causing the diffraction phenomenon is, for example, a condition in which a pitch p of the diffraction pattern 1C is larger than (wavelength λ of exposure light in whole image exposure)/(refractive index n of diffraction pattern with respect to exposure light in whole image exposure) (p>λ/n). When EUV light is used for the whole image exposure, because the refractive index n can be assumed to be substantially 1, exposure light of a shorter wavelength than a size of the pitch of the diffraction pattern 1C is used.

Further, the minimum pitch of the diffraction pattern 1C depends on a wavelength of exposure light used at the time of forming the diffraction pattern 1C. Therefore, it is desired to use exposure light of a smaller wavelength than that of exposure light used at the time of forming the diffraction pattern 1C, as exposure light used for the whole image exposure. For example, when i ray (wavelength: 365 nanometers) is used at the time of forming the diffraction pattern 1C, the whole image exposure is performed by using krypton fluoride (KrF) excimer laser (wavelength: 248 nanometers), argon fluoride (ArF) excimer laser (wavelength: 193 nanometers), F2 excimer laser (wavelength: 157 nanometers), or extreme ultraviolet lithography (EUV) (wavelength: 13.6 nanometers), having a shorter wavelength than i ray. Immersion exposure or electron beams can be used for forming the diffraction pattern 1C and for the whole image exposure. In the present embodiment, for example, the diffraction pattern 1C is formed by using the ArF excimer laser, and the whole image exposure is performed by using the EUV.

When the whole image exposure is performed from above the diffraction pattern 1C, a light intensity distribution appears on the intermediate layer 2, the resist layer 3X, and the pattern forming layer 4X. In FIG. 1, an area having a weak light intensity distribution of the light intensity distribution is indicated by a low intensity area A1, and an area having a strong light intensity distribution is indicated by a high intensity area B1. In the low intensity area A1, the light intensity distribution becomes weak due to diffraction of exposure light by the diffraction pattern 1C. In the high intensity area B1, the light intensity distribution becomes strong due to diffraction of exposure light by the diffraction pattern 1C.

A resist pattern is formed on the resist layer 3X among the intermediate layer 2, the resist layer 3X, and the pattern forming layer 4X by development processing after exposure. When the resist layer 3X is a positive resist, in the low intensity area A1 of the resist layer 3X, the resist pattern remains by the development processing after exposure, and in the high intensity area B1 of the resist layer 3X, the resist pattern is removed by the development processing after exposure. After performing the development processing on the resist layer 3X, the pattern forming layer 4X is etched, by using the resist layer 3X after development as a mask, thereby forming a desired pattern on the pattern forming layer 4.

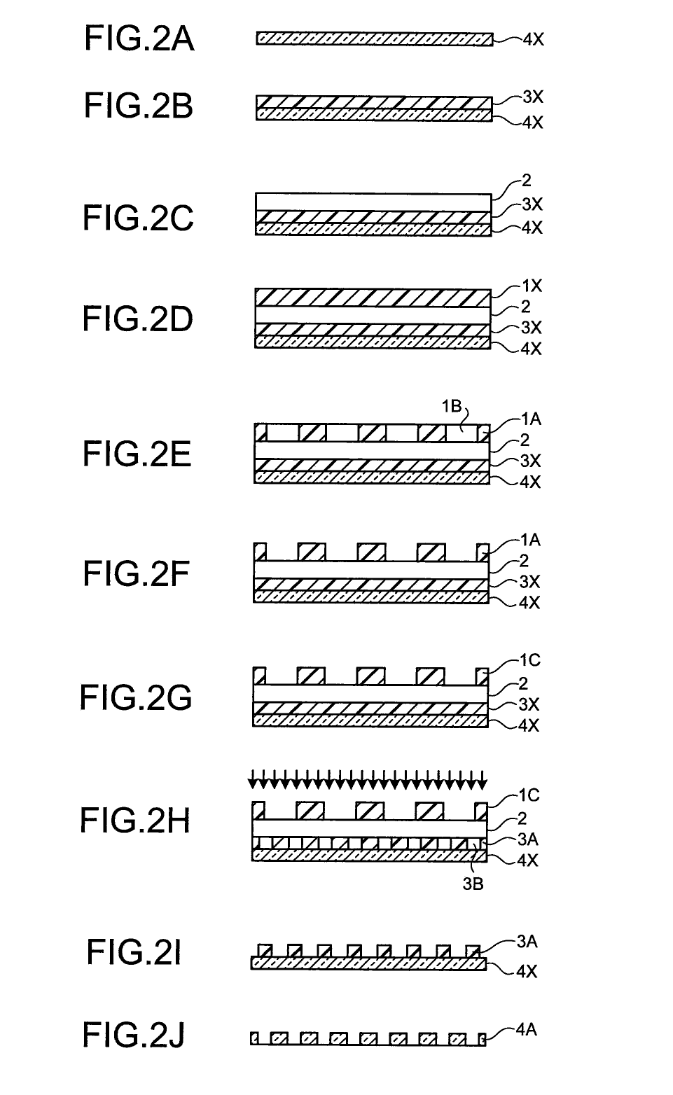

A pattern forming process procedure with respect to the pattern forming layer is explained next. FIGS. 2A to 2J depict a pattern forming process procedure with respect to the pattern forming layer. FIGS. 2A to 2J are cross sections of the substrate.

As shown in FIG. 2A, the substrate (the pattern forming layer 4X) is prepared, and as shown in FIG. 2B, a first resist layer 3X is laminated on the pattern forming layer 4X. The first resist layer 3X is a resist layer that is exposed to diffracted light by whole image exposure with respect to the diffraction pattern 1C later. The pattern forming layer 4X is not limited to a semiconductor substrate, and can be any layer such as a metal layer or an insulating layer.

After the resist layer 3X is laminated on the pattern forming layer 4X, as shown in FIG. 2C, the intermediate layer 2 is laminated on the resist layer 3X. Further, as shown in FIG. 2D, a second resist layer 1X is laminated on the intermediate layer 2. The second resist layer 1X is used for forming the diffraction pattern 1C.

After the second resist layer 1X is laminated on the intermediate layer 2, as shown in FIG. 2E, exposure (for example, exposure by the ArF excimer laser) to the second resist layer 1X is performed. The exposure to the second resist layer 1X uses the photomask and the projection optical system. Accordingly, a position (a pattern 1A) corresponding to a light shielding portion of the photomask, of the second resist layer 1X, is not exposed, and a position (a pattern 1B) of a translucent portion is exposed.

After the second resist layer 1X is exposed, as shown in FIG. 2F, development is performed, and post exposure bake (PEB) is then performed as shown in FIG. 2G. Only the pattern 1A is left, and the pattern 1B is removed by development. The pattern 1A is hardened by PEB to become the diffraction pattern 1C.

Thereafter, as shown in FIG. 2H, whole image exposure is performed from above the diffraction pattern 1C. At this time, the whole image exposure is performed by exposure light having a shorter wavelength than that used at the time of exposing the second resist layer 1X (for example, whole image exposure by the EUV). Accordingly, predetermined positions corresponding to the diffraction pattern 1C (a position of a resist pattern 3A described later) of the first resist layer 3X are not exposed, and positions other than the resist pattern 3A (a removal pattern 3B) are exposed.

After the whole image exposure is performed from above the diffraction pattern 1C, the diffraction pattern 1C and the intermediate layer 2 are removed. Development and PEB are further performed. Accordingly, as shown in FIG. 21, only the resist pattern 3A is left, and the removal pattern 3B is removed. Thereafter, the pattern forming layer 4X is etched, by using the resist layer 3A after development as the mask, thereby forming a desired pattern (an after-etching pattern) 4A is formed as shown in FIG. 2J.

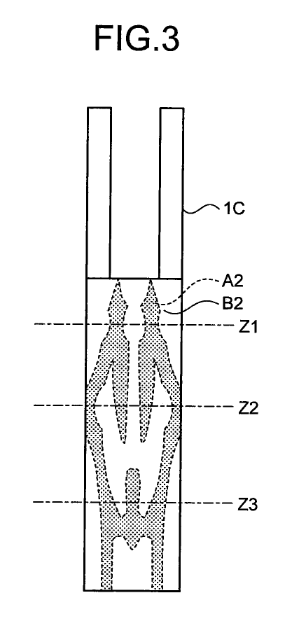

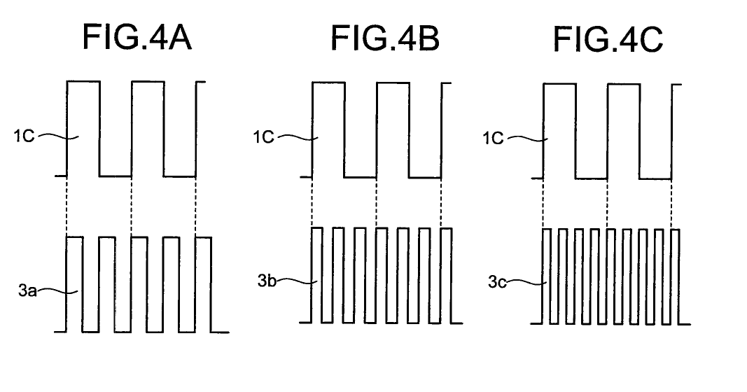

A relation between an arrangement position of the first resist layer 3X and the light intensity distribution is explained next. FIG. 3 is a schematic diagram for explaining the relation between the arrangement position of the first resist layer and the light intensity distribution. In FIG. 3, a case that a space width and a line width of the diffraction pattern 1C are the same is explained. As shown in FIG. 3, when the whole image exposure is performed from above the diffraction pattern 1C, the light intensity distribution (contrast) is generated below the diffraction pattern 1C. It is determined which part of the first resist layer 3X is to be exposed according to the light intensity distribution. Therefore, it is determined which part of the first resist layer 3X becomes the resist pattern after development according to the light intensity distribution. Accordingly, in the present embodiment, it is determined beforehand at which position the first resist layer 3X is arranged based on the light intensity distribution corresponding to the diffraction pattern 1C.

In FIG. 3, a case that the light intensity distribution is formed of a low intensity area A2 having a weak light intensity distribution and a high intensity area B2 having a strong light intensity distribution is explained. In this case, if the first resist layer 3X is arranged at heights of interlayer positions Z1 to Z3 (a contrast-pattern forming position), the resist pattern is formed at positions corresponding to the low intensity area A2 at the respective interlayer positions Z1 to Z3.

For example, a distribution (a line width) of the low intensity area A2 at the height of the interlayer position Z1 is half the line width (a space width) of the diffraction pattern 1C. Therefore, if the first resist layer 3X is arranged at the height of the interlayer position Z1, a resist pattern having double the pitch of the diffraction pattern 1C can be formed.

The resist pattern having double the pitch is a resist pattern having half the line width of the diffraction pattern 1C. Likewise, a resist pattern having a threefold pitch is a resist pattern having one-third the line width of the diffraction pattern 1C, and a resist pattern having a fourfold pitch is a resist pattern having one-fourth the line width of the diffraction pattern 1C. In the present embodiment, a case that the line width of the resist pattern is 1/N of the line width of the diffraction pattern 1C is referred to as N-fold pitch.

A distribution (a line width) of the low intensity area A2 at the height of the interlayer position Z2 is one fourth the line width of the diffraction pattern 1C. Therefore, if the first resist layer 3X is arranged at the height of the interlayer position Z2, a resist pattern having fourfold the pitch of the diffraction pattern 1C can be formed.

Further, a distribution (a line width) of the low intensity area A2 at the height of the interlayer position Z3 is one third the line width of the diffraction pattern 1C. Therefore, if the first resist layer 3X is arranged at the height of the interlayer position Z3, a resist pattern having threefold the pitch of the diffraction pattern 1C can be formed. The low intensity area A2 shown in FIG. 3 is one example only, and other light intensity distributions can be formed according to the size of the diffraction pattern 1C and an exposure wavelength (whole image exposure wavelength) of the whole image exposure.

Configurations of the resist pattern having double, threefold, and fourfold the pitch of the diffraction pattern 1C are explained next. FIGS. 4A to 4C depict configuration examples of the resist pattern with respect to the diffraction pattern 1C. In FIGS. 4A to 4C, sectional views of the diffraction pattern 1C are shown as in FIGS. 1 and 3.

As described above, in the pattern forming method according to the present embodiment, the shape and position of the low intensity area can be adjusted at respective interlayer positions, and thus the size and position of a pattern finally acquired can be adjusted. Further, although not shown in FIG. 3, by providing an intermediate layer on the resist and appropriately adjusting a film thickness thereof, a light intensity distribution to be formed on the resist can be adjusted without adjusting a film thickness of the resist or the like.

FIG. 4A depicts a sectional configuration when a resist pattern 3a having double the pitch of the diffraction pattern 1C is formed. FIG. 4B depicts a sectional configuration when a resist pattern 3b having threefold the pitch of the diffraction pattern 1C is formed. FIG. 4C depicts a sectional configuration when a resist pattern 3c having fourfold the pitch of the diffraction pattern 1C is formed.

A relation between the size of the diffraction pattern 1C and a light intensity distribution is explained next. In the present embodiment, because a resist pattern is formed on the first resist layer 3X by using diffraction of exposure light by the diffraction pattern 1C, a light intensity distribution that appears on the first resist layer 3X varies according to the size (line width and space width) of the diffraction pattern 1C. In other words, the size and shape of the resist pattern to be formed vary according to the size (bias amount) of the diffraction pattern 1C.

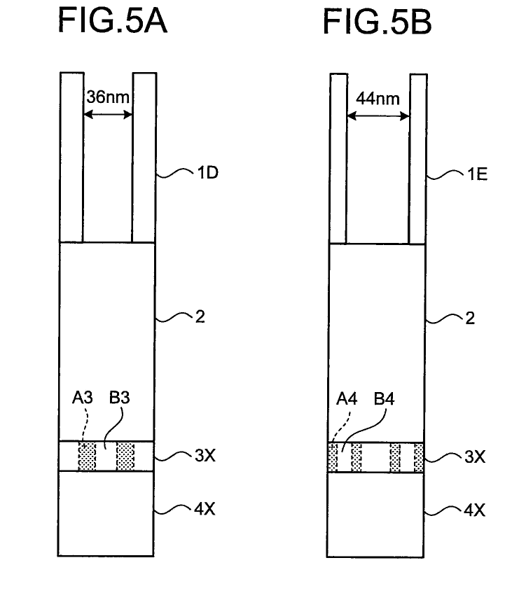

FIGS. 5A and 5B are schematic diagram for explaining the relation between the size of the diffraction pattern and a light intensity distribution. FIG. 5A depicts a case that a diffraction pattern 1D in which a size of an opening is 36 nanometers is used as the diffraction pattern 1C, and FIG. 5B depicts a case that a diffraction pattern 1E in which the size of the opening is 44 nanometers is used as the diffraction pattern 1C. In FIGS. 5A and 5B, a light intensity distribution in the intermediate layer 2 and the pattern forming layer 4X is not shown.

For example, as shown in FIG. 5A, when the size of the opening of the diffraction pattern 1D is 36 nanometers, a low intensity area A3 and a high intensity area B3 are formed in which a resist pattern having double the pitch of the diffraction pattern 1D can be formed. Further, as shown in FIG. 5B, when the size of the opening of the diffraction pattern 1E is 44 nanometers, a low intensity area A4 and a high intensity area B4 are formed in which a resist pattern having fourfold the pitch of the diffraction pattern 1E can be formed. The low intensity areas A3 and A4, and the high intensity areas B3 and B4 are one example only, and other light intensity distributions can be formed according to the thickness of the intermediate layer 2 and the whole image exposure wavelength.

In the present embodiment, a light intensity distribution is calculated based on the size of the diffraction pattern 1C, the whole image exposure wavelength, and an arrangement position of the first resist layer 3X. Therefore, the size of the diffraction pattern 1C, the whole image exposure wavelength, and the arrangement position of the first resist layer 3X are predetermined. The diffraction pattern 1C is then changed (corrected) based on the calculated light intensity distribution. At this time, the diffraction pattern 1C is changed so that a light intensity distribution capable of forming a desired pattern can be acquired. The arrangement position of the first resist layer 3X or the whole image exposure wavelength can be changed so that a light intensity distribution capable of forming a desired pattern can be acquired based on the calculated light intensity distribution. When the diffraction pattern 1C is to be changed, a mask pattern of the mask used at the time of forming the diffraction pattern 1C is corrected. Further, when the arrangement position of the first resist layer 3X is to be changed, the thickness of the intermediate layer 2 or the like is changed.

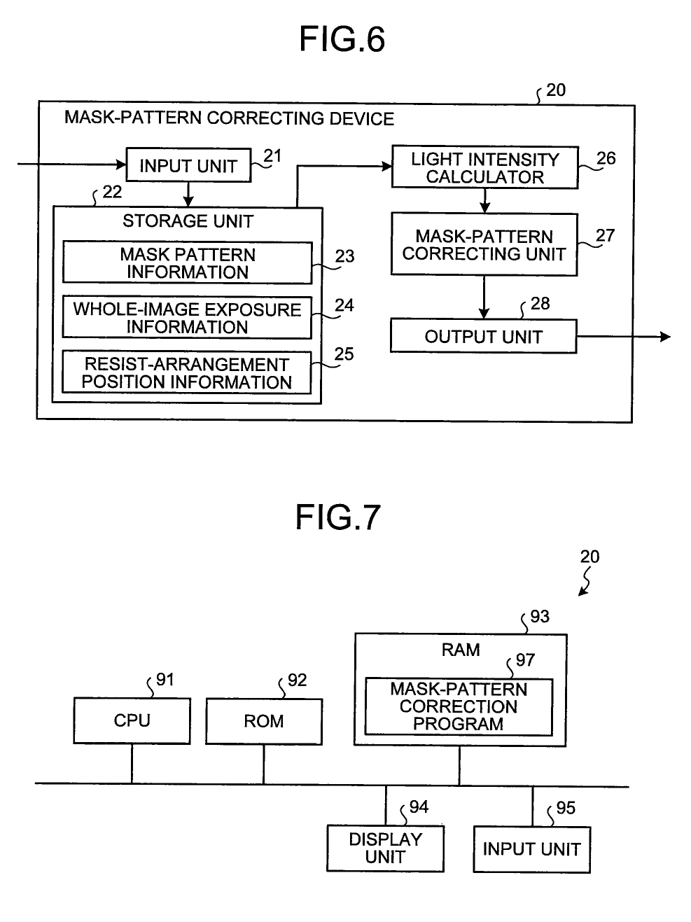

Correction of the mask pattern used at the time of forming the diffraction pattern 1C is performed by a mask-pattern correcting device (a mask-pattern generating device). FIG. 6 is a block diagram of a configuration of the mask-pattern correcting device. A mask-pattern correcting device 20 is a computer that corrects the mask pattern, and includes an input unit 21, a storage unit 22, a light intensity calculator 26, a mask-pattern correcting unit 27, and an output unit 28.

The input unit 21 inputs various pieces of information to be stored in the storage unit 22 and transmits the information to the storage unit 22. The storage unit 22 is a memory that stores mask pattern information 23, whole-image exposure information 24, and resist-arrangement position information 25 as information transmitted from the input unit 21. The mask pattern information 23 is information of the mask pattern used at the time of forming the diffraction pattern 1C. The whole-image exposure information 24 relates to a condition of whole image exposure, and includes, for example, a wavelength value used for whole image exposure and an optical constant of an upper layer film in this wavelength. The resist-arrangement position information 25 relates to the arrangement position of the first resist layer 3X (a distance from the diffraction pattern 1C in a thickness direction).

The light intensity calculator 26 calculates a light intensity distribution to be formed below the diffraction pattern 1C by using the mask pattern information 23, the whole-image exposure information 24, and the resist-arrangement position information 25 in the storage unit 22.

The mask-pattern correcting unit 27 corrects the mask pattern in the mask pattern information 23, so that a desired pattern can be formed based on the light intensity distribution calculated by the light intensity calculator 26. The output unit 28 outputs the mask pattern information 23 corrected by the mask-pattern correcting unit 27 to the outside.

FIG. 7 depicts a hardware configuration of the mask-pattern correcting device 20. The mask-pattern correcting device 20 is a device such as a computer that generates a mask pattern (pattern data) of a photomask used in an exposure process in a semiconductor manufacturing process, and includes a central processing unit (CPU) 91, a read only memory (ROM) 92, a random access memory (RAM) 93, a display unit 94, and an input unit 95. In the mask-pattern correcting device 20, the CPU 91, the ROM 92, the RAM 93, the display unit 94, and the input unit 95 are connected to each other via a bus line.

The CPU 91 corrects the mask pattern by using a mask-pattern correction program 97, which is a computer program for correcting the mask pattern. The display unit 94 is a display such as a liquid crystal monitor, and displays the mask pattern information 23, the whole-image exposure information 24, the resist-arrangement position information 25, the light intensity distribution, and a mask pattern after correction based on an instruction from the CPU 91. The input unit 95 includes a mouse and a keyboard, and inputs instruction information (a parameter and the like required for correcting the mask pattern) input from outside by a user. The instruction information input to the input unit 95 is transmitted to the CPU 91.

The mask-pattern correction program 97 is stored in the ROM 92, and loaded to the RAM 93 via the bus line. The CPU 91 executes the mask-pattern correction program 97 loaded into the RAM 93. Specifically, in the mask-pattern correcting device 20, the CPU 91 reads the mask-pattern correction program 97 from the ROM 92, expands it in a program storage area in the RAM 93, and executes various types of processing, according to an instruction input from the input unit 95 by the user. The CPU 91 temporarily stores various pieces of data generated at the time of performing the various types of processing in a data storage area formed in the RAM 93.

The mask-pattern correcting device 20 can calculate the light intensity distribution to be formed below the diffraction pattern 1C (such as the resist layer 3X) and output the calculated light intensity distribution. In this case, the light intensity distribution calculated by the light intensity calculator 26 is output from the output unit 28. Moreover, the mask-pattern correcting device 20 uses a light-intensity-distribution calculation program (optical-image-intensity calculation program) instead of the mask-pattern correction program 97. The light-intensity-distribution calculation program is a computer program that calculates the light intensity distribution to be formed below the diffraction pattern 1C. The light-intensity-distribution calculation program is stored in the ROM 92 and is loaded into the RAM 93 via the bus line in the similar manner to the mask-pattern correction program 97. The CPU 91 executes the light-intensity-distribution calculation program loaded into the RAM 93.

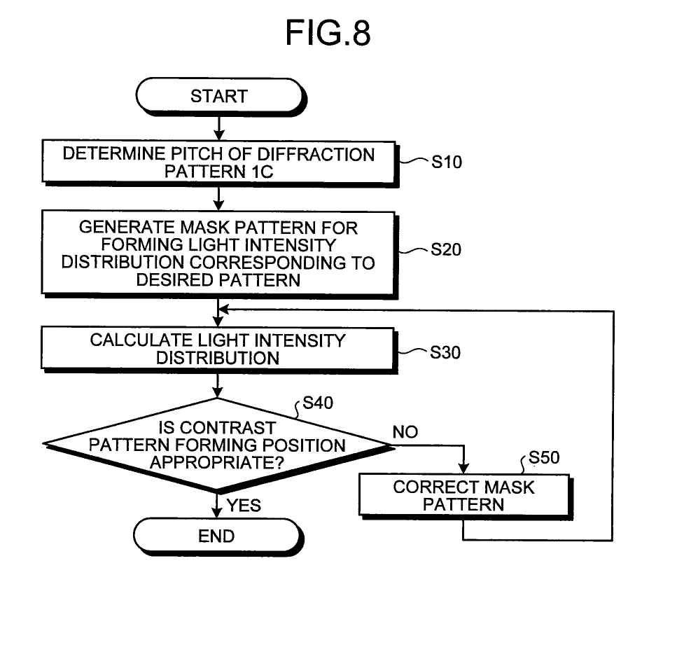

A correction process procedure of the mask pattern based on a light intensity distribution is explained next. FIG. 8 is a flowchart of the correction process procedure of the mask pattern based on a light intensity distribution. First, a pitch of the diffraction pattern 1C is determined (Step S10). The pitch of the diffraction pattern 1C is determined based on the size of the pattern (desired pattern) to be formed on the pattern forming layer 4X. For example, when a pattern is formed on the pattern forming layer 4X at a pitch threefold the pitch of the diffraction pattern 1C, the diffraction pattern 1C needs only to be formed in a size threefold the size of a pattern to be formed. Further, the pitch of the diffraction pattern 1C can be determined based on the whole image exposure wavelength and the arrangement position of the first resist layer 3X.

Thereafter, a mask pattern of the diffraction pattern 1C capable of forming a light intensity distribution corresponding to the desired pattern (a pattern to be formed on the pattern forming layer 4X) is generated (Step S20). The generated mask pattern is input to the mask-pattern correcting device 20 as the mask pattern information 23. Further, the whole image exposure wavelength and the optical constant are input to the mask-pattern correcting device 20 as the whole-image exposure information 24, and the arrangement position of the first resist layer 3X is input to the mask-pattern correcting device 20 as the resist-arrangement position information 25. Specifically, the mask pattern information 23, the whole-image exposure information 24, and the resist-arrangement position information 25 are input from the input unit 21 and transmitted to the storage unit 22. The storage unit 22 stores the mask pattern information 23, the whole-image exposure information 24, and the resist-arrangement position information 25.

The light intensity calculator 26 then calculates a light intensity distribution when whole image exposure is performed from above the generated mask pattern (the diffraction pattern 1C). Specifically, the light intensity calculator 26 calculates the light intensity distribution to be formed below the diffraction pattern 1C by using the mask pattern information 23, the whole-image exposure information 24, and the resist-arrangement position information 25 in the storage unit 22 (Step S30).

The mask-pattern correcting unit 27 determines whether a contrast pattern forming position (a low intensity area and a high intensity area) in the light intensity distribution is appropriate based on the calculated light intensity distribution and the resist-arrangement position information 25 (Step S40). When the contrast pattern forming position is not appropriate (NO at Step S40), the mask-pattern correcting unit 27 corrects the mask pattern for forming the diffraction pattern 1C (Step S50). When the contrast pattern forming position is inappropriate, the mask-pattern correcting unit 27 can change the arrangement position of the first resist layer 3X (thickness of the intermediate layer 2 or the like).

Thereafter, the mask-pattern correcting device 20 repeats the process at Steps S30 to S50 until the contrast pattern forming position in the light intensity distribution becomes appropriate. That is, after correcting the mask pattern, the light intensity calculator 26 calculates a light intensity distribution when whole image exposure is performed from above the corrected mask pattern (Step S30). The mask-pattern correcting unit 27 determines whether the contrast pattern forming position in the light intensity distribution is appropriate based on the calculated light intensity distribution and the resist-arrangement position information 25 (Step S40).

When the contrast pattern forming position is not appropriate (NO at Step S40), the mask-pattern correcting unit 27 corrects the mask pattern for forming the diffraction pattern 1C again (Step S50). On the other hand, when the contrast pattern forming position is appropriate (YES at Step S40), the mask-pattern correcting unit 27 determines the mask pattern, in which the contrast pattern forming position has been determined to be appropriate, as the mask pattern for the diffraction pattern 1C. The determined mask pattern is output from the output unit 28 to the outside as required. Thereafter, the determined mask pattern is used to generate a photomask. The desired pattern 4A is then formed according to the process procedure explained in FIGS. 2A to 2J.

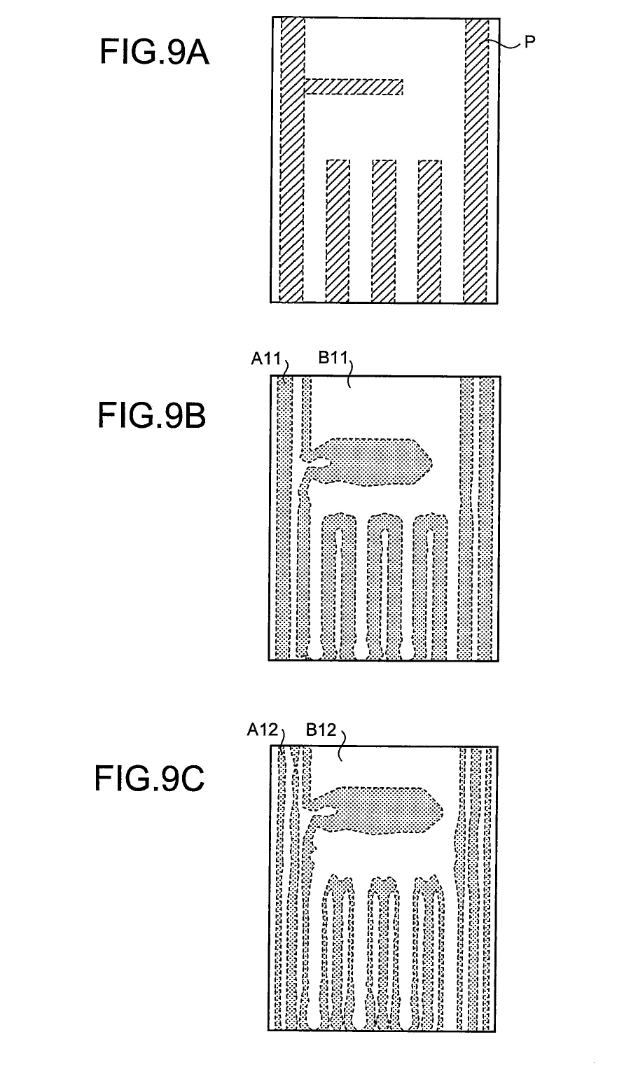

The diffraction pattern 1C and a light intensity distribution as viewed from above are explained next. FIGS. 9A to 90 depict an example of the diffraction pattern and a light intensity distribution as viewed from above. FIG. 9A is one example of the diffraction pattern 1C. In FIG. 9A, an actual mask pattern of the diffraction pattern 1C is indicated by pattern P. The diffraction pattern 1C includes, for example, a periodic pattern and a non-periodic pattern.

FIG. 9B depicts a light intensity distribution when the desired pattern 4A having a double pitch is formed by using the diffraction pattern 1C. In FIG. 9B, the low intensity area is indicated by a low intensity area A11, and the high intensity area is indicated by a high intensity area B11.

FIG. 9C depicts a light intensity distribution when the desired pattern 4A having a threefold pitch is formed by using the diffraction pattern 1C. In FIG. 9C, the low intensity area is indicated by a low intensity area A12, and the high intensity area is indicated by a high intensity area B12.

When a semiconductor device (a semiconductor integrated circuit) is manufactured, a process for forming the desired pattern 4A through whole image exposure using the diffraction pattern 1C, development, and etching is repeated in each layer. Accordingly, the semiconductor device is manufactured.

In the present embodiment, a case that the intermediate layer 2 is arranged between the diffraction pattern 1C and the resist layer 3X is explained. However, other layers other than the intermediate layer 2 can be laminated between the diffraction pattern 1C and the resist layer 3X.

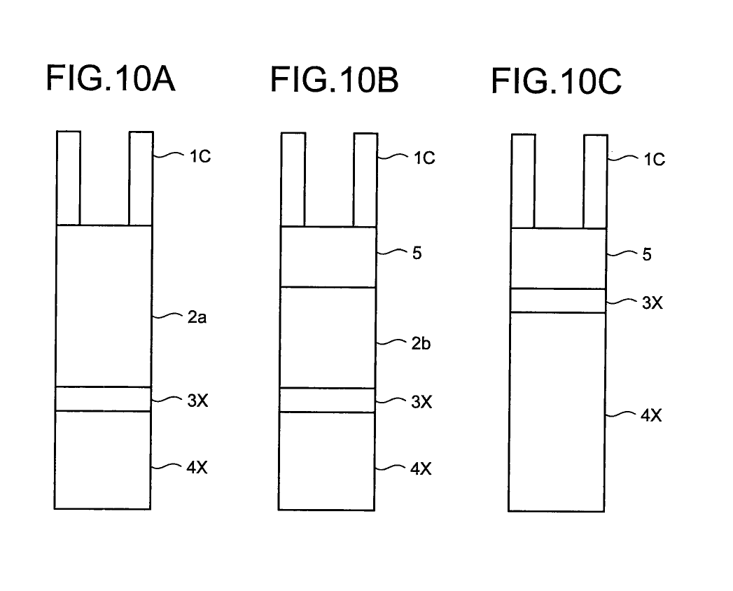

FIGS. 10A to 10C are schematic diagram for explaining various layers arranged between the diffraction pattern and the resist layer. FIG. 10A depicts a case that an intermediate layer 2a is arranged between the diffraction pattern 1C and the resist layer 3X, which corresponds to the sectional configuration of the substrate explained in FIG. 1.

FIG. 10B depicts a case that a lower layer film 5 and an intermediate layer 2b are arranged between the diffraction pattern 1C and the resist layer 3X. The lower layer film 5 can be a bottom anti-reflective coating (BARC) used at the time of exposing the diffraction pattern 1C, or a protective coating required in the process. Also in the case of configuration shown in FIG. 10B, the thickness of the lower layer film 5 and the intermediate layer 2b can be determined based on a light intensity distribution as in the configuration shown in FIG. 10A.

FIG. 10C depicts a case that the lower layer film 5 is arranged between the diffraction pattern 1C and the resist layer 3X. Also in the case of configuration shown in FIG. 10C, the thickness of the lower layer film 5 can be determined based on a light intensity distribution as in the configuration shown in FIG. 10A.

As shown in FIGS. 10A to 10C, by laminating various films between the diffraction pattern 1C and the resist layer 3X, and adjusting the film thickness of the films to be laminated, a desired light intensity distribution can be formed on the resist layer 3X. Accordingly, a desired resist pattern can be formed by using the resist layer 3X, and the resist pattern can be transferred to the pattern forming layer 4X as a mask.

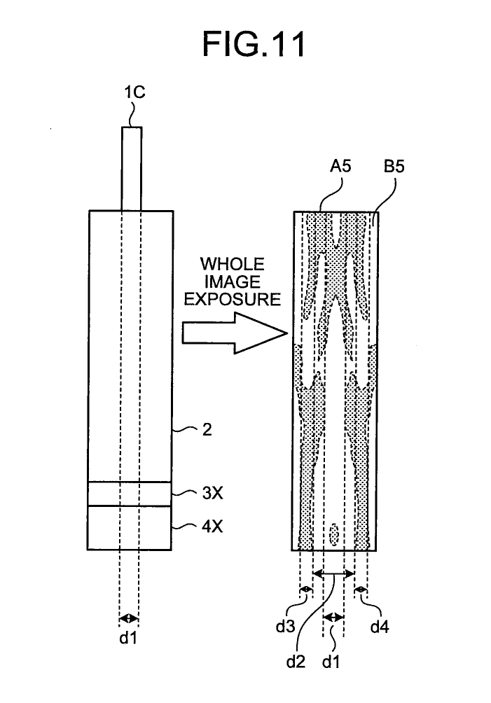

In FIG. 1 and FIGS. 9A to 9C, a case that a desired pattern is formed at a pattern edge of the diffraction pattern 1C (almost immediately below the diffraction pattern 1C) is explained. However, a desired pattern can be formed at a position other than the pattern edge of the diffraction pattern 1C. FIG. 11 depicts a light intensity distribution when a desired pattern is formed at a position other than the pattern edge of the diffraction pattern. A light intensity distribution capable of forming a desired pattern at a position other than the pattern edge can be formed after whole image exposure by adjusting the pattern shape of the diffraction pattern 1C, the thickness of the intermediate layer 2, and the like. In FIG. 11, the light intensity distribution includes a low intensity area A5 having a weak light intensity distribution and a high intensity area B5 having a strong light intensity distribution. The low intensity area A5 having a weak light intensity distribution is formed at a position other than the pattern edge of the diffraction pattern 1C. FIG. 11 depicts a case that when a line width of the diffraction pattern 1C is a width d1, a desired pattern is not formed almost immediately below the diffraction pattern 1C (in an area with a width d2 larger than the width d1), and desired patterns (patterns with width d3 and d4) are formed in an area outside of the width d2.

When whole image exposure is performed from above the diffraction pattern 1C, if a duty (a ratio between a line size and a space size) of the diffraction pattern 1C is different, the light intensity distribution in the first resist layer 3X becomes different. Therefore, by variously changing the duty and the pitch of the diffraction pattern 1C, resist patterns having various sizes (arbitrary resist patterns) can be formed in the same layer. Further, the height of the diffraction pattern 1C affects the light intensity distribution formed on the resist. Accordingly, by adjusting the height of the diffraction pattern 1C, the light intensity distribution to be formed on the resist can be adjusted.

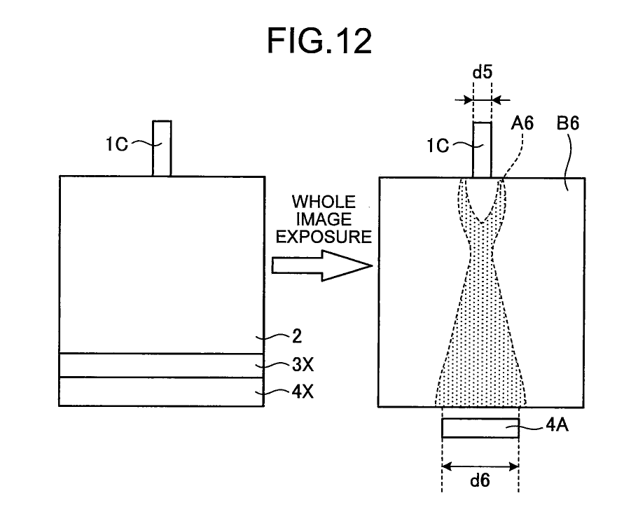

Further, a resist pattern having a larger size than the diffraction pattern 1C can be formed by making the diffraction pattern 1C an isolated pattern. FIG. 12 depicts a light intensity distribution when an isolated pattern is used. In FIG. 12, a light intensity distribution when the diffraction pattern 1C is the isolated pattern is shown.

The isolated pattern is a pattern in which the pitch (space width) of the diffraction pattern 1C is larger than the size (line width) of the diffraction pattern 1C by a predetermined value or a predetermined ratio. Also in this case, a light intensity distribution capable of forming a desired pattern at a position other than the pattern edge can be formed after whole image exposure, by adjusting the pattern shape of the diffraction pattern 1C, the thickness of the intermediate layer 2, and the like. In FIG. 12, the light intensity distribution includes a low intensity area A6 having a weak light intensity distribution and a high intensity area B6 having a strong light intensity distribution. The low intensity area A6 having a weak light intensity distribution has a larger width than the pattern size of the diffraction pattern 1C. FIG. 12 depicts a case that when the line width of the diffraction pattern 1C is a width d5, the desired pattern 4A having a larger size (a width d6) than the width d5 is formed. For example, when the pattern pitch is 200 nanometers and the width of the diffraction pattern 1C is 20 nanometers, the desired pattern 4A having a width of 80 nanometers can be formed.

When a resist pattern having a larger size than the diffraction pattern 1C and a resist pattern having a smaller size than the diffraction pattern 1C such as a double pitch are to be simultaneously formed in the same layer, the pattern shape of the diffraction pattern 1C and the thickness of the intermediate layer 2 need to be adjusted so that the both resist patterns can be formed. Therefore, the diffraction pattern 1C and the intermediate layer 2 are adjusted to have the pattern shape and the thickness, respectively, that can form the resist pattern having a larger size than the diffraction pattern 1C and the resist pattern having a smaller size than the diffraction pattern 1C.

In the present embodiment, a case that exposure light having a shorter wavelength than the pitch of the diffraction pattern 1C is used for whole image exposure is explained. However, exposure light having a longer wavelength than the pitch of the diffraction pattern 1C can be used for whole image exposure. In this case, the exposure process uses near-field exposure light. When exposure light having a longer wavelength than the size of the opening of the diffraction pattern is used for whole image exposure, a distribution of near-field light has directions respectively different according to a polarization direction in a polarized state of light. Therefore, a resist pattern having a double pitch can be formed immediately below the diffraction pattern 1C.

Also when the whole image exposure wavelength is longer than the size of the opening of the diffraction pattern, the desired pattern 4A can be formed according to the procedure explained in FIGS. 2A to 2J and FIG. 8. Accordingly, even when the whole image exposure wavelength is longer than the size of the opening of the diffraction pattern, a pattern finer than the diffraction pattern 1C (a pattern having a double pitch) can be formed. When the whole image exposure wavelength is longer than the size of the opening of the diffraction pattern, the resist pattern formed by whole image exposure can be used to further perform whole image exposure. In other words, a resist-pattern forming process by whole image exposure can be repeated several times.

In this case, in the pattern-formation process procedure shown in FIGS. 2A to 2J, a new intermediate layer (the second intermediate layer) and a third resist layer are laminated between the resist layer 3X and the pattern forming layer 4X. Specifically, the third resist layer is laminated on the pattern forming layer 4X, and the second intermediate layer is laminated on the third resist layer. The first resist layer 3X is then laminated on the second intermediate layer. Further, as explained in FIGS. 2C and 2D, the intermediate layer 2 and the second resist layer 1X are laminated on the first resist layer 3X in this order. As shown in FIG. 2H, the resist pattern 3A is formed on the first resist layer 3X. At this time, whole image exposure is performed by using exposure light having a longer wavelength than that used at the time of exposing the second resist layer 1X. Thereafter, exposure is performed with respect to the third resist layer formed below the resist pattern 3A by using the resist pattern 3A as a diffraction pattern. At this time, whole image exposure is performed by using exposure light having a longer wavelength than that used at the time of exposing the first resist layer 3X. Accordingly, a finer pattern (a pattern having a double pitch) than the resist pattern 3A finer than the diffraction pattern 1C can be formed. Therefore, a pattern having fourfold the pitch of the diffraction pattern 1C can be formed.

Further, the resist pattern 3A can be formed on the second resist layer 3X by using interference between reflected light from a lower layer film formed below the second resist layer 3X and irradiated light to the second resist layer 3X.

According to the present embodiment, because whole image exposure is performed from above the diffraction pattern 1C with a wavelength different from the size of the minimum pitch of the diffraction pattern 1C, resolution of the pattern can be increased, and various patterns finer than the diffraction pattern 1C can be easily formed.

Because whole image exposure is performed with respect to the diffraction pattern 1C above the resist layer 3X by using the intermediate layer 2 and the lower layer film 5, the distance between the resist layer 3X and the diffraction pattern 1C can be easily adjusted, and pattern formation based on a light intensity distribution can be easily performed.

Further, because pattern formation is performed based on a light intensity distribution, a desired pattern can be formed at positions other than the pattern edge of the diffraction pattern 1C (almost immediately below the diffraction pattern 1C). Therefore, various patterns can be formed at various positions.

Further, because the diffraction pattern 1C is formed in various sizes by variously changing the duty and pitch of the diffraction pattern 1C, various patterns can be formed on the pattern forming layer 4X. Further, because the mask pattern of the diffraction pattern 1C is corrected based on a light intensity distribution, a pattern can be easily formed on the pattern forming layer 4X.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern forming method comprising:
laminating a first resist layer on an upper layer side of a pattern forming layer used for forming a desired pattern on a substrate;
forming a diffraction pattern having an opening opened at a predetermined pitch p for diffracting exposure light on an upper layer side than the first resist layer;
performing whole image exposure with respect to the diffraction pattern in which a refractive index with respect to the exposure light is n, with diffracted light acquired by irradiation of exposure light having a wavelength λ from above the diffraction pattern, which is then diffracted by the diffraction pattern; and
forming a desired pattern on the pattern forming layer by using a resist pattern formed by developing the first resist layer, wherein
the predetermined pitch p of the diffraction pattern, the wavelength λ of the exposure light, and the refractive index n satisfy a condition of p>λ/n.

2. The pattern forming method according to claim 1, wherein the diffraction pattern is formed on an intermediate layer formed on the first resist layer.

3. The pattern forming method according to claim 1, wherein the diffraction pattern is formed on a bottom anti-reflective coating formed on the first resist layer or a predetermined protective coating formed on the first resist layer.

4. The pattern forming method according to claim 1, wherein an interlayer distance between the diffraction pattern and the first resist layer in a film thickness direction is a distance determined based on a light intensity distribution in the first resist layer at a time of performing the whole image exposure.

5. The pattern forming method according to claim 1, wherein the desired pattern is formed at a position different from below an edge position of the diffraction pattern.

6. The pattern forming method according to claim 1, wherein the whole image exposure is performed by using EUV light.

7. The pattern forming method according to claim 1, wherein the diffraction pattern is a pattern formed based on a light intensity distribution in the first resist layer at a time of performing the whole image exposure.

8. The pattern forming method according to claim 1, wherein the diffraction pattern is an isolated pattern having a pattern pitch larger than a pattern width by a predetermined value or a predetermined ratio.

9. The pattern forming method according to claim 1, wherein the light intensity distribution is calculated by using information of the diffraction pattern and a condition at a time of performing the whole image exposure.

10. A pattern forming method comprising:
laminating a first resist layer on an upper layer side of a pattern forming layer used for forming a desired pattern on a substrate;;
forming a second resist layer on an upper layer side than the first resist layer, and forming a diffraction pattern having a predetermined opening for diffracting exposure light by applying a lithography process using exposure light of a first wavelength to the second resist layer;
performing exposure with respect to the first resist layer with diffracted light acquired by irradiation of exposure light having a second wavelength smaller than the first wavelength by whole image exposure from above the diffraction pattern, which is then diffracted by the diffraction pattern; and
forming a desired pattern on the pattern forming layer by using the resist layer formed by developing the first resist layer.

11. The pattern forming method according to claim 10, wherein the diffraction pattern is formed on an intermediate layer formed on the first resist layer.

12. The pattern forming method according to claim 10, wherein the diffraction pattern is formed on a bottom anti-reflective coating formed on the first resist layer or a predetermined protective coating formed on the first resist layer.

13. The pattern forming method according to claim 10, wherein an interlayer distance between the diffraction pattern and the first resist layer in a film thickness direction is a distance determined based on a light intensity distribution in the first resist layer at a time of performing the whole image exposure.

14. The pattern forming method according to claim 10, wherein the desired pattern is formed at a position different from below an edge position of the diffraction pattern.

15. The pattern forming method according to claim 10, wherein the whole image exposure is performed by using EUV light.

16. The pattern forming method according to claim 10, wherein the diffraction pattern is a pattern formed based on a light intensity distribution in the first resist layer at a time of performing the whole image exposure.

17. The pattern forming method according to claim 10, wherein the diffraction pattern is an isolated pattern having a pattern pitch larger than a pattern width by a predetermined value or a predetermined ratio.

18. The pattern forming method according to claim 10, wherein the light intensity distribution is calculated by using information of the diffraction pattern and a condition at a time of performing the whole image exposure.

19. A computer program product having a computer readable medium including programmed instructions that can be executed on a computer and are for calculating an optical image to a resist, wherein the instructions, when executed by the computer, cause the computer to perform:
calculating an optical image to a first resist layer when performing whole image exposure with respect to a diffraction pattern in which a refractive index with respect to exposure light is n, with diffracted light acquired by irradiation of the exposure light having a wavelength λ from above the diffraction pattern, which is then diffracted by the diffraction pattern, with respect to a substrate on which the first resist layer is laminated on an upper layer side of a pattern forming layer used for forming a desired pattern and the diffraction pattern having an opening opened at a predetermined pitch p for diffracting the exposure light is formed on an upper layer side of the first resist layer.
